(19) United States
(12) Patent Application Publication
(10) Pub. No.: US 2009/0181864 A1
(43) Pub. Date: Jul. 16, 2009

(54) ACTIVE CONTROL FOR DROPLET-BASED MICROFLUIDICS

(76) Inventors: Nam Trung Nguyen, Singapore (SG); Teck Neng Wong, Singapore (SG); Chee Kiong John Chai, Singapore (SG); Cheng Wang, Singapore (SG); Yit Fatt Yap, Singapore (SG); Teck Hui Ting, Singapore (SG)

Correspondence Address: WOMBLE CARLYLE SANDRIDGE & RICE, PLLC, ATTN: PATENT DOCKETING, P.O. BOX 7037, ATLANTA, GA, 30357-0037, US

(21) Appl. No.: 12/295,366

(22) PCT Filed: Mar. 30, 2007
(86) PCT No.: PCT/SG07/00087

§ 371 Date: Sep. 30, 2008

Related U.S. Application Data
(60) Provisional application No. 60/787,796, filed on Mar. 31, 2006.

(51) Int. Cl. C40B 60/00; B81B 1/00

(52) U.S. Cl. 506/33; 204/601; 204/451; 422/99

(57) ABSTRACT

A microfluidic network provides active control of characteristics of at least one micro-droplet. The microfluidic network includes at least one junction of at least one first channel and at least one second channel; and an electrically controlled actuator at or adjacent the junction to induce a change in the characteristics of the at least one micro-droplet. A corresponding method employs an electrically controlled actuator at or adjacent a junction to induce a change in the characteristics of a micro-droplet.

### TECHNICAL FIELD

This invention relates to active control for droplet-based microfluidics and refers particularly, though not exclusively, to active control for droplet-based microfluidics for use in lab-on-chip platforms, more particularly for cell analysis.

### DEFINITION

Throughout this specification a reference to micro is to be taken as including a reference to nano.

Throughout this specification a reference to a micro droplet or droplet is to be taken as including a reference to a micro bubble or bubble respectively.

### BACKGROUND

In the emerging field of discrete (or digital) microfluidics, instead of using continuous flow to handle liquid transport, mixing and chemical reaction, only a minute amount of liquid is needed for a micro-droplet or nano-droplet (henceforth “micro-droplet”). This is droplet-based microfluidics or nanofluidics (henceforth “microfluidics”). Chemical and biochemical reactions can be contained inside the droplets. The reactants as well as the reaction products are protected. Instead of using conventional microfluidic components such as micropumps, microvalves, micromixers, in droplet-based microfluidics new apparatus and methods are required for generating, transport, manipulation, merging, chopping, sorting and switching of micro-droplets.

The advent of micro-chemical analysis systems had led to a growing interest in microfabricated fluidic systems with length scales in the range of one to a hundred microns. Such miniaturization promises realization of assays with low reagent volumes and costs. It permits scaling at the micrometer range, coupled with a potential or path for implementing multiplexed, arrayed assays of small size that may be used in laboratories and point-of-care medical devices. These are commonly known as lab-on-a-chip (“LOC”) and μTASs (micrototal analytical systems).

The simplest apparatus for micro-droplet generation is a ‘T-junction’. A microchannel system consists of one large carrier channel and a small injection channel perpendicular to the carrier channel. Through this configuration, two immiscible liquids are forced to merge, so that one liquid forms droplets in the other. This passive formation process depends on the interfacial tension and the flow rates of the two liquids. Using a network with multiple T-junctions, encapsulation of different liquids is possible. This may also used be for manipulation of droplets such as sorting or cutting.

Droplets and Bubbles are fluid entities surrounded by another immiscible fluid. Bubble or droplet formation is a complex physical phenomenon determined by the relationships between key parameters such as bubble size, formation frequency, sample flow rate and surface tension. A number of assumptions may be made: a fixed flow rate ratio between air and sample liquid, small bubble or droplet size and the incompressibility of air. Since bubbles may be formed in micro scale and the flows may be steady state, mass related forces such as inertial force, momentum force and buoyancy force are neglected.

As the growing bubble or droplet is in a flowing surfactant liquid, the surfactant concentration at the bubble surface is not uniformly distributed and thus a gradient of surface tension on the bubble surface develops. The presence of the surface tension gradient leads to a Marangoni force acting on the bubble. If the surfactant solution is dilute, the Marangoni force may be assumed to be negligible, and thus the force balance equation including only the drag force of the sample flow and the surface tension at the injection port is expressed as:

$${F}_{drag} = {F}_{surface tension} \\ \frac{1}{2} {C}_{D} ρ {u}_{s}^{2} {A}_{D} = {C}_{s} π {D}_{i} σ \qquad ( 1 )$$

where u_{S}, A_{D}, Dᵢ, and σ are the average velocity of the sample flow, the effective drag surface, the diameter of the injection opening, and the surface tension, respectively; and C_{D} and C_{S} are the drag coefficient and the coefficient for the surface tension.

The drag coefficient of a sphere at a low Reynolds number Re is calculated as C_{D}=24/Re. The coefficient C_{S} depends on the contact angle and the shape of the injection port. In this model C_{S} is assumed constant. The effective drag surface area A_{D} grows with the bubble.

If the bubble or droplet is a sphere, the effective drag surface area at the detachment moment is:

$${A}_{D} = \frac{π {D}_{b}^{2}}{2} \qquad ( 2 )$$

where D_{b} is the diameter of the bubble or droplet. If the bubble or droplet is initially small, the surface tension is large enough to keep the bubble at the injection port. At the detachment moment, due to continuous bubble or droplet growth, the drag force is large enough to release the bubble. Substituting (2) into (1) results in the bubble diameter:

$${D}_{b} = 2 \sqrt{\frac{{C}_{s}}{{C}_{D}} {D}_{i} \frac{σ}{{ρ}_{s} {u}_{s}^{2}}} \qquad ( 3 )$$

The formation frequency can be estimated from the air or liquid flow rate \dot{Q}ₐ and the bubble or droplet volume V_{b} as:

f=\dot{Q}ₐ/V_{b} (4)

Using the bubble or droplet diameter D_{b} and the relation \dot{Q}ₐ=α\dot{Q}ₛ, the formation frequency in (4) can be expressed as:

$$f = \frac{3 α {D}_{s}^{2}}{16 {( {C}_{s} {D}_{i} / {C}_{D} )}^{\frac{3}{2}}} \frac{{ρ}^{\frac{3}{2}} {u}_{s}^{4}}{{σ}^{\frac{3}{2}}} \qquad ( 5 )$$

A shorter mixing path and possible chaotic advection inside droplets can be achieved by forming droplets of a solvent and a solute. For formation of droplets, the flows of the solvent and the solute enter from the two sides with a middle inlet being used for the carrier fluid, which is immiscible to both the solvent and the solute. The formation behavior of droplets depends on the capillary number Ca, and the flow rate ratios between the solvent, the solute and the carrier fluid. At a low capillary number, the solvent and solute can merge into a sample droplet and mix rapidly due to chaotic advection inside the droplet.

By increasing the capillary number at the same flow rate ratio, the droplets form separately and are not able to merge and mix. By further increasing the capillary number, alternate droplets become smaller and unstable. At a high capillary number, the three streams flow side-by-side, as in the case of immiscible fluids.

The droplet train formed in such a configuration may be stored over an extended period because the carrier fluid (for example, oil) can protect the aqueous sample from evaporation. The long-term stability of the sample allows protein crystallization in the microscale. If the solute and solvent merge and mix, the flow pattern inside the mixed droplet could make it possible for there to be chaotic advection inside the mixed droplet.

The inverse effect of passive droplet formation is passive droplet breakup. At a T-junction, a droplet can be divided into two smaller droplets. This process is normally passive. The size of the divided droplets depends on the fluidic resistances of the branches at the T-j unction.

Direct electrowetting and electrowetting on dielectric are well suited for droplet-based microfluidics. Electrowetting can be used for dispensing and transporting a liquid droplet. The aqueous droplet is surrounded by immiscible oil. The droplet is aligned with a control electrode underneath the droplet. The control electrode is normally about 1 mm×1 mm and is used to change the hydrophobicity of the solid/liquid interface. 800-nm Parylene C layer works as the insulator. The ground electrode is made of transparent ITO for optical investigation. 60-nm Teflon layer was coated over the surface to make it hydrophobic. Electrowetting allows different droplet handling operations such as droplet dispensing, droplet merging, droplet cutting, and droplet transport. These basic operations allow merging and fast mixing of liquid droplets. The device is able to transport liquid droplets surrounded by air. The liquid/air system may have a disadvantage of evaporation. However, the evaporation rate is slow due to the encapsulated small space around the droplet.

The effect of thermocapillary is another way for manipulating surface tension. The temperature dependency of surface tension of a liquid/gas/solid system causes this effect. The viscosity and surface tension of a liquid decrease with increasing temperature. A gas bubble moves against the temperature gradient toward a higher temperature. A liquid plug moves along the temperature gradient toward a lower temperature. These phenomena are also called Marangoni effects. In practical applications, the temperature gradient can be generated using integrated heaters. FIG. 6 shows our initial results on controlling the movement of a liquid plug.

Previously, a shear force was used to generate micro droplets. The force balance between shear and surface tension is described in equation (1) above. The shear force can only be controlled by the flow rate, while the interfacial tension can be controlled by surfactant concentration. Control over droplet formation has been achieved by external syringe pumps and surfactant diluted in the liquid. The droplet formation process was passive. On-chip control was therefore not possible.

### SUMMARY

According to an exemplary aspect there is provided a microfluidic network for active control of characteristics of at least one micro-droplet. The microfluidic network comprises at least one junction of at least one first channel and at least one second channel; and an electrically controlled actuator at or adjacent the junction to induce a change in the characteristics of the at least one micro-droplet.

The control of the characteristics of the at least one droplet may be one or more of: droplet formation, droplet break-up, combining of droplets, joining of droplets, and merging of droplets.

The electrically controlled actuator may be at least one of: an actuator for hydrodynamic disturbance, a piezoelectric actuator, at least one microheater, an external electromagnet, and at least one microwetting cell.

The at least one microwetting cell may comprise a first electrode in the at least one first channel, and at least one second electrode at or adjacent the at least one junction. The at least one second electrode may be insulated with a hydrophobic material. The first electrode may be able to have direct contact with a sample fluid in the at least one first channel. The at least one second channel may comprise at least one side branch, the at least one second electrode being in the at least one side branch. There may be two side branches. There may be a first array of second electrodes in a first side branch, and a second array of second electrodes in a second side branch. The first array of second electrodes and the second array of second electrodes may be separately controllable.

Alternatively, the at least one second channel comprises at least one side branch, the at least one microheater being in the at least one side branch. There may be two side branches. There may be a first array of microheaters in a first side branch, and a second array of microheaters in a second side branch. The first array of microheaters and the second array of microheaters may be separately controllable.

The piezoelectric actuator may be operatively connected to the at least one second channel and may effect hydrodynamic disturbance along the at least one second channel to the at least one junction.

The external electromagnetic may be used for generating a magnetic field for controlling the characteristics of the at least one micro-droplet. Magnetic beads may be distributable at an interface of the at least one micro-droplet. The external electromagnet may control the characteristics of the at least one micro-droplet by the external magnetic field. The magnetic beads may act as an agitator inside the at least one micro-a droplet. Agitation by stirring may be able to be performed.

The at least one junction may be at least one of: a T-junction, a cross junction, a bisected V-junction, and a Y-shaped junction.

According to another exemplary aspect there is provided a lab-on chip device comprising a carrier fluid reservoir operatively connected to the second channel of the microfluidic network as described above;
electric signal input to, and output from, the microfluidic network for sensing characteristics of the microfluidic network controlling the microfluidic network respectively;
optical signal input to, and output from, the microfluidic network for sensing characteristics of, and receiving output from, the microfluidic network respectively;
a waste reservoir operatively connected to an output of the microfluidic network for receiving outlet waste carrier fluid; and
at least one reservoir for at least one reagent and at least one sample fluids and being operatively connected to the at least one first channel.

The lab-on-chip device may further comprise at least one of: a preprocessor with hydrodynamic focusing, a detection unit, and a cell switching unit.

According to a further exemplary aspect there is provided a method for active control of characteristics of at least one micro-droplet using a microfluidic network comprising at least one junction of at least one first channel and at least one second channel. The method comprises using an electrically controlled actuator at or adjacent the at least one junction to induce a change in the characteristics of the at least one micro-droplet.

The control of the characteristics of the at least one droplet may be one of: droplet formation, droplet break-up, combining of droplets, joining of droplets, and merging of droplets.

The electrically controlled actuator may be at least one of: an actuator for hydrodynamic disturbance, a piezoelectric actuator, at least one microheater, an external electromagnet, and at least one microwetting cell.

The at least one microwetting cell may comprise a first electrode in the at least one first channel, and at least one second electrode at or adjacent the at least one junction. The at least one second electrode may be insulated with a hydrophobic material. The first electrode may have direct contact with a sample fluid in the at least one first channel. The at least one second channel may comprise at least one side branch, the at least one second electrode being in the at least one side branch. There may be two side branches. There may be a first array of second electrodes in a first side branch, and a second array of second electrodes in a second side branch. The first array of second electrodes and the second array of second electrodes may be separately controlled.

Alternatively, the at least one second channel may comprise at least one side branch, the at least one microheater being in the at least one side branch. There may be two side branches. There may be a first array of microheaters in a first side branch, and a second array of microheaters in a second side branch. The first array of microheaters and the second array of microheaters may be separately controlled.

The piezoelectric actuator may be operatively connected to the at least one second channel and may effect hydrodynamic disturbance along the at least one second channel to the at least one junction.

The external electromagnet may form an external magnetic field to control the characteristics of the at least one micro-droplet. Magnetic beads may be distributed at an interface of the at least one micro-droplet. The external electromagnet may control the characteristics of the at least one micro-droplet by the external magnetic field. The magnetic beads may act as an agitator inside the at least one micro droplet. Agitation by stirring may be performed.

The at least one junction may be is at least one of: a T-junction, a cross junction, a bisected V-junction, and a Y-shaped junction.

According to a final aspect there is provided a sample concentrator for concentrating a plurality of micro-droplets each containing a cell into a single, large droplet containing a plurality of cells, the sample concentrator comprising: a plurality of microfluidic networks as described above, at each junction of the at least one junction of each of the plurality of microfluidic networks there being an outlet for removal of carrier fluid.

### BRIEF DESCRIPTION OF THE DRAWINGS

In order that the invention may be fully understood and readily put into practical effect there shall now be described by way of non-limitative example only exemplary embodiments of the present invention, the description being with reference to the accompanying illustrative drawings.

In the drawings:

FIG. 1 is a schematic representation of an exemplary embodiment of active control of droplet formation using hydrodynamic disturbance;

FIG. 2 is four representations of droplet formation in the exemplary embodiment of FIG. 1 at different hydrodynamic disturbance frequencies;

FIG. 3 is two plots of the measured flow field inside a micro-droplet of the exemplary embodiment of FIG. 1;

FIG. 4 is a representation showing active micro-droplet control with Marangoni force with (a) being a microfluidic network with heaters at the inlets for controlling the droplet formation process; and (b) is a microfluidic network with heaters at the inlets for controlling the droplet break-up process;

FIG. 5 is a representation showing droplet formation with (a) being with no heating; (b) having heating of the oil inlet; and (c) having heating of the water inlet;

FIG. 6 is a representation showing droplet break-up with (a) being with no heating; (b) having an active bottom heater; and (c) having an active top heater;

FIG. 7 is a representation showing an exemplary embodiment of a microfluidic network for active control of micro-droplet formation using hydrodynamic disturbance;

FIG. 8 is a representation showing an exemplary embodiment of a microfluidic network for active control of micro-droplet formation using electrowetting;

FIG. 9 is a representation showing an exemplary embodiment of a microfluidic network for active control of micro-droplet formation using a thermocapillary effect;

FIG. 10 is a representation of an exemplary embodiment of a microchannel network for active control of micro-droplet breakup using thermocapillary force;

FIG. 11 is a representation of an exemplary embodiment of a microfluidic network for active control of micro-droplet breakup using electrowetting;

FIG. 12 is a representation of an exemplary embodiment of a microfluidic network for active control of micro-droplet merging using thermocapillary force;

FIG. 13 is a representation of an exemplary embodiment of a lab-on-a-chip platform with active control of micro-droplets;

FIG. 14 is a representation of an exemplary embodiment of a lab-on-a chip for cell encapsulation and sorting;

FIG. 15 is a representation of an exemplary embodiment of a sample concentrator; and

FIG. 16 is a representation of an exemplary embodiment of a microfluidic network using a magnetic field for active control of micro-droplets.

### DETAILED DESCRIPTION OF EXEMPLARY EMBODIMENTS

In the exemplary embodiments like reference numerals are used for like components.

In the exemplary embodiments, a third force is used to affect the force balance during the process of droplet formation. This allows active control over the size of a droplet and its formation frequency without changing the flow rates and without addition of surfactant to the liquid. The forces used, and a simple implementation may include, but are not limited to:
Hydrodynamic force: using a pulsating excitation, a time-periodic component is added to the usually time-independent shear force. The droplet size and the formation frequency can be controlled by the magnitude and the frequency of the excitation.
Marangoni force: According to the scaling law, surface-related forces such as electrostatic force or thermocapillary force are dominant in the micro scale. Electrowetting utilizes electrostatic force to manipulate the surface energy at the gas/liquid/solid or liquid/liquid/solid contact line. This may be used to manipulate the surface energy at the droplet injection port using electrowetting or thermocapillary effect, thus bypassing the use of a surfactant.
Magnetic force: The magnetic force is actually a body force. Although body force is not dominant in the micro scale, manipulating the body force can still affect the force balance. With magnetic beads distributed at the droplet interface, the formation and breakup process can be controlled by an external magnetic field formed by an external electromagnet.
Other forces: All other effects changing the force balance at the solid/liquid/gas interfacial line during the formation and breakup process can be used for this purpose.

The flow field inside a droplet can be controlled by manipulating the shear force at the interface around the droplet. This shear force can be induced by the forces mentioned above. The techniques manipulate the flow field inside micro droplets using the following forces:
Hydrodynamic force: channel shapes can passively manipulate flow fields around a droplet and, consequently, through the shear force, its internal flow field. Alternatively, pulsating external flow may be used as an option of hydrodynamic force for controlling flow field inside the droplet.
Marangoni force: using electrode structures in the microchannels, an additional shear force created by electrowetting or thermocapillary can manipulate the flow field inside the droplet.
Magnetic force: with an external magnetic field, magnetic beads can act as an agitator inside a droplet. Agitation as by stirring is therefore possible.
Other forces: all other physical effects which can induce a shear force at the droplet interface can serve the purpose described above.

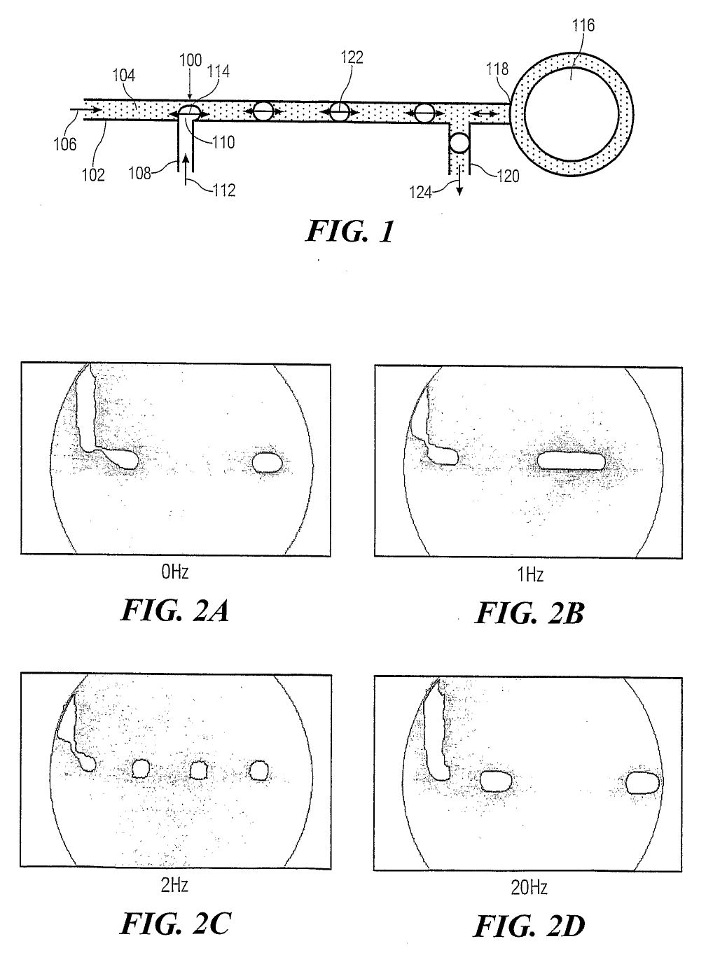

One way to show the effect of a third force in the formation process is inducing hydrodynamic disturbance. The schematic of the device is depicted in FIG. 1. This shows a conventional. T-junction 100 with a carrier channel 102 for the carrier oil 104 flowing in the direction of the arrow 106; and an injection channel 108 for the aqueous liquid 110 flowing in the direction of the arrow 112. Hydrodynamic disturbance 114 is induced at the T-junction 100 and along the carrier channel 102 after the junction 100 (after being in the sense of flow direction 106) by a piezoelectric disc 116 located at the end 118 of the channel 102 beyond the outlet channel 120. The hydrodynamic disturbance 114 is carried by the carrier oil 104 from the piezoelectric disc 116 to the junction 100. The magnitude and frequency of the disturbance can be adjusted by the amplitude and frequency of the drive voltage for the piezoelectric disc 116. Micro droplets 122 of the aqueous liquid 110 are formed in the carrier oil 104 and are subject to the hydrodynamic disturbance 114 while in the carrier channel 102. The droplets 122 pass through outlet channel 120 in the direction of arrow 124 and are no longer subject to the hydrodynamic disturbance 114.

In the results shown in FIG. 2, the flow rates and the amplitude of the drive voltage were kept constant. The effect of the disturbance frequency on the formation process can be clearly observed due to the change in size of the droplets. In FIG. 2(a), at 0 Hz, conventional passive formation results in regular droplet size at a constant formation frequency. In FIG. 2(b) at 1 Hz, the induced hydrodynamic disturbance imbalances in the forces at the solid/liquid/liquid interfacial line results in an early release of the droplet. A smaller droplet was formed. Since the flow rates and flow rate ratios are kept constant, a larger droplet is subsequently formed. FIG. 2(c) is at 2 Hz, and the disturbance is synchronized with the natural formation frequency (of the passive formation process) and results in regular droplets, which are significantly smaller then those created by passive formation. FIG. 2(d) is at the higher frequency of 5 Hz and, due to the strong viscous damping, the magnitude of the disturbance is smaller than those of drag forces and interfacial tension. Therefore, high-frequency disturbance does not significantly affect the droplet formation process. The droplet size and formation frequency is similar to those formed by passive formation,

The other effect of hydrodynamic disturbance is the shaking movement of the droplets 122 as symbolically depicted in FIG. 1. This movement induces a time dependent shear stress around the droplets 122, which causes chaotic advection inside droplet and improves mixing.

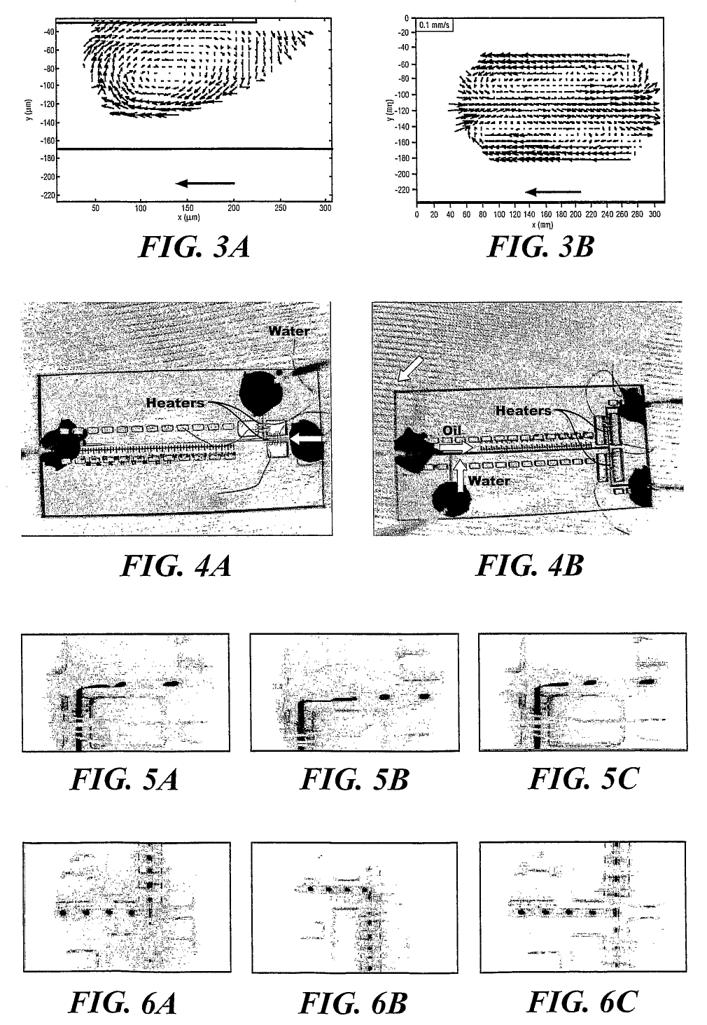

By using a modified micro-PIV technique, the flow field inside the droplets 122 was measured and this is shown in FIG. 3.

This shows that active control of droplet formation (droplet size, formation frequency) and of the field inside a droplet is possible with a third force applied to the droplet interfaces.

As the Marangonic force is induced thermally, the effect is also known as thermocapillary effect as explained above. This is shown in FIG. 4. In FIG. 4(a), both inlets for the sample flow (water) and carrier flow (oil) are surrounded by resistive heaters to control the temperature of the water and oil. In FIG. 4(b), the outlet branches have the same length and are also controlled by resistive heaters. The flow rate of the sample flow (water with fluorescent dye) was kept at 500 μL/hr. the flow rate ratio between the sample and the carrier (oil) was kept at 1:4. FIG. 5 shows the results and show that the droplet size and the formation frequency can be controlled by the temperature of the inlets. It is preferred for the heater to be integrated directly at the injection port, where the sample joins the carrier channel.

FIG. 6 shows break-up of droplets using heaters. If both heaters are not active, the droplet will be broken up at the end of the carrier channel. The size of the droplets on both branches is determined by their fluidic impedances. The passive breakup process can be seen in FIG. 6(a). FIG. 6(b) shows the result when the bottom heater is active. The Marangoni force and the lower fluidic resistance due to lower viscosity at high temperature pull the droplet to the bottom branch. Only small droplets escape to the top branch. If the temperature is right, the entire droplet can be switched into the bottom branch. In the later case, the oil-to-water ratio is changed from 4:1 to 2:1. This effect is reproducible for the top branch. FIG. 6(c) shows a clear switch of the droplets to the top branch, as the top heater is activated.

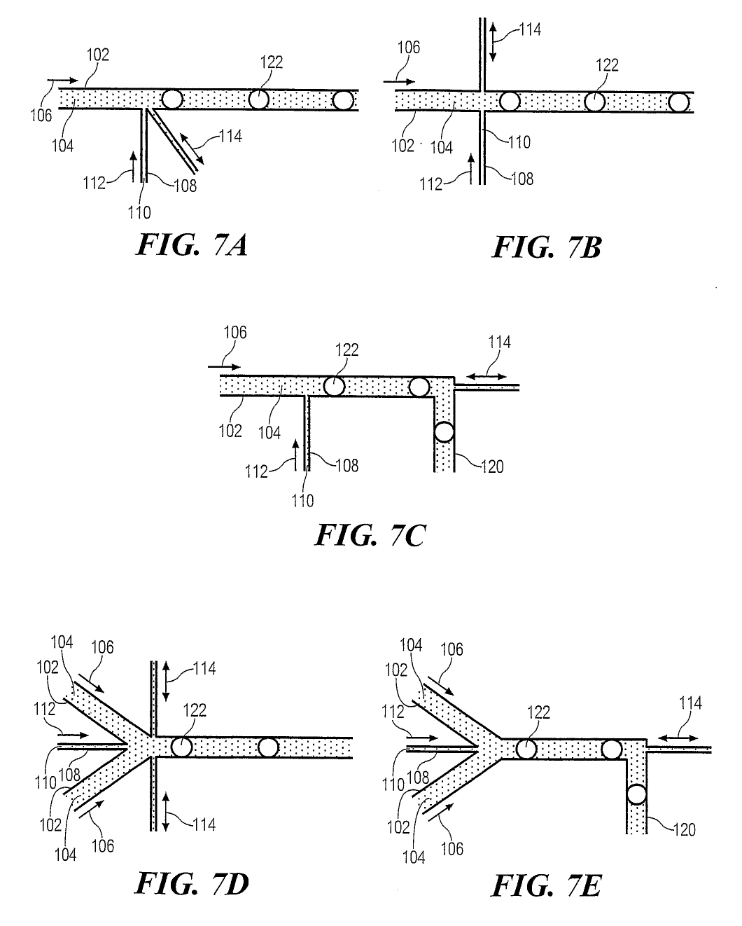

Possible configurations of a microfluidic device for active control of droplet formation using an actuator to induce hydrodynamic disturbance are depicted in FIG. 7. Here, the same reference numerals are used for the same components as in FIG. 1. This shows that the microfluidic network has a junction that couples the carrier inlet 102 and the aqueous inlet 108 that may be one or more of: a T-junction 100, a cross junction 126, a bisected V-junction 128, a Y-shaped junction (not shown) and so forth. There is also an actuator to induce hydrodynamic disturbance 114 into the carrier channel at or after the junction 100, 126, 128 and that is carried to the junction 100, 126, 128 by the carrier oil 104. This may be along a separate actuator channel or channels as shown in (a), (b) and (d). The actuation may be before, at or after the junction.

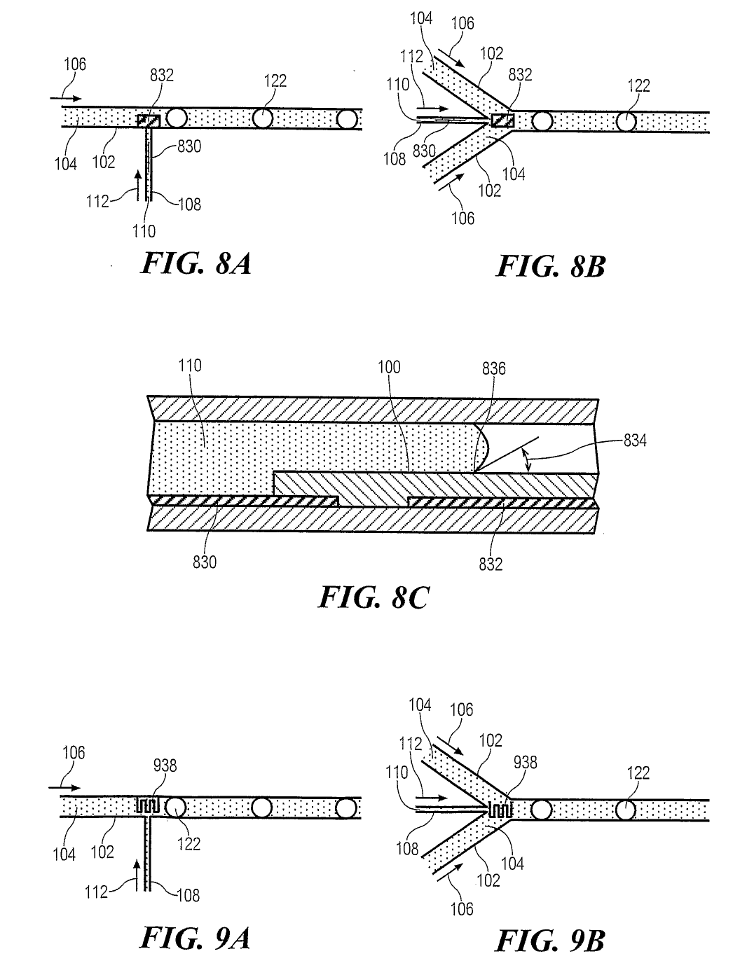

FIGS. 8(a) and 8(b) show a microfluidic network that may be any one or more of the forms shown in FIG. 7 but where there is a microwetting cell 730 integrated at the junction between the carrier channel 102 and the injection channel 108. The microwetting cell 830 has two electrodes: a positive electrode 830 in the injection channel 108 that has direct contact with the sample 110, which is an electrolyte; and a negative, or insulated, electrode 832 at the junction where the formation process occurs. The second electrode 832 is insulated to the sample by a hydrophobic material such as “Teflon”.

By controlling the voltage between the two electrodes 830, 832, the contact angle 834 at the droplet interface 836 can be controlled. Since the interfacial tension is a direct function of the contact angle 834, the formation process can be controlled by the applied voltage.

FIG. 9 shows a microfluidic network that may be any one or more of the forms shown in FIG. 7 but where there is a microheater 938 integrated at the junction between the carrier channel 102 and the injection channel 108.

By controlling the current or voltage of heater 938, the temperature at the droplet interface can be controlled. Since the interfacial tension strongly depends on the temperature, the heater 938 can actively control the droplet formation process at the junction.

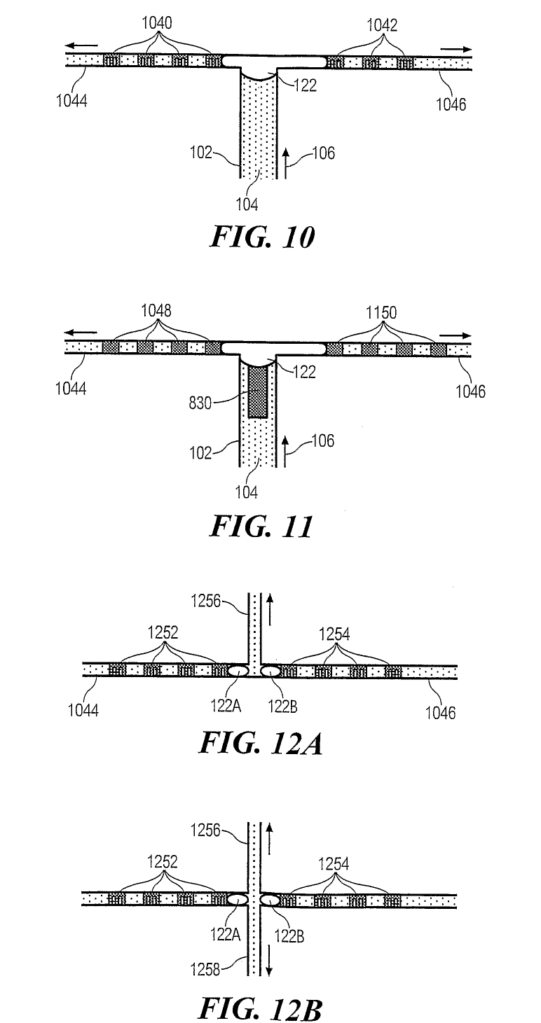

FIG. 10 shows a microfluidic network that may be any one or more of the forms shown in FIG. 7 but where there is a first array of micro heaters 1040 integrated in a first branch 1044 of the side branches, and a second array of micro heaters 1042 integrated in a second branch 1046 of the side branches. The first array 1040 and the second array 1042 are separately controllable, and may be identical. Alternatively, they may be different. There may be the same number of micro heaters in the arrays 1040, 1042, or there may be a different number of micro heaters in the two arrays 1040, 1042 (as illustrated).

Controlling the temperature distribution in the side branches 1044, 1046 allow the active breakup control of droplets 122. Instead of using fluidic resistance in conventional passive methods, the interfacial tension at each side of the droplet determines the breakup ratio. Precise dispensing can be achieved by controlling the temperature of the micro heaters in the arrays 1040, 1042.

FIG. 11 shows a microfluidic network that may be any one or more of the forms shown in FIG. 7 but where there is a first array 1148 of electrowetting cells in the first side branch 1044, and a second array 1150 of electrowetting cells in the second side branch 1046. The first array 1148 and the second array 1150 are separately controllable, and may be identical. Alternatively, they may be different. There may be the same number of electrowetting cells in the arrays 1148, 1150 (as illustrated), or there may be a different number of electrowetting cells in the two arrays 1148, 1150.

Each array 1148, 1150 of electrowetting cells is an array of insulated electrodes 832 in the respective side branches 1044, 1046. Controlling the voltage differences between the insulated electrodes and the positive electrode 830 allows precise cutting and breakup of the droplet 122 in the side channels 1148, 1150.

FIG. 12 shows a microfluidic network for droplet merging that may be any one or more of the forms shown in FIG. 7 but where there is a first array of micro heaters 1252 integrated in the first branch 1044 of the side branches, and a second array of micro heaters 1254 integrated in the second branch 1046 of the side branches. The first array 1252 and the second array 1254 are separately controllable, and may be identical. Alternatively, they may be different. There may be the same number of micro heaters in the arrays 1252, 1254 (as illustrated), or there may be a different number of micro heaters in the two arrays 1252, 1254. The arrays of microheaters 1252, 1254 are as actuators.

If heaters 1252 and 1254 are both activated, droplets 122A and 122B are forced to merge at the junction. The immiscible carrier fluid between them can escape through channels 1256 and 1258.

In FIG. 12(a) there is one escape channel 1256 for the carrier fluid 104. In FIG. 12(b) there are two escape channels 1256, 1258 for the carrier fluid 104.

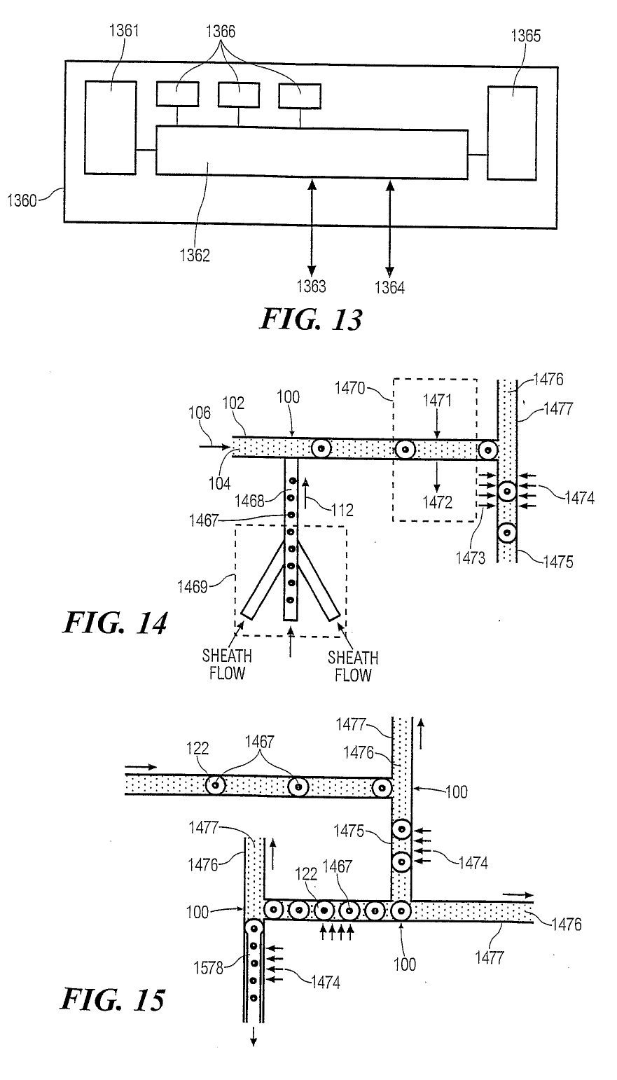

FIG. 13 shows the schematics of a lab-on chip device 1360 for cell encapsulation and sorting. The device 1360 consists of several components:
a carrier fluid 104 reservoir 1361 operatively connected to carrier channel 102 of a microfluidic network 1362;
the microfluidic network 1362 may be according any of the previously described exemplary embodiments;
electric signals 1363 are input to and received from the microfluidic network 1362. Sensing is for sensing characteristics of the microfluidic network 1362, and control is for controlling the microfluidic network 1362 as is described above;
optical signals 1364 are input to and received from the microfluidic network 1362. Input for obtaining desired characteristics of the sample fluid 110, and receiving is for receiving an optical signal that provides the desired characteristics;
a waste reservoir 1365 is operatively connected to an output of the microfluidic network 1362 and receives the outlet waste carrier fluid 104 and any other waste fluid; and
reservoirs 1366 for reagents and sample fluids and operatively connected to sample fluid channel 108.

The lab-on-chip device may also include a preprocessor with hydrodynamic focusing, a detection unit, and a cell switching unit.

In FIG. 14, the sheath flows are the side flows that squeeze the sample flow with cells. With the sheath flows, the cells are able to line up in a single line for further processing such as encapsulation. The FIGURE shows apparatus for focusing cells 1467 in a buffer solution 1468 in a single line using conventional hydrodynamic focusing 1469. The sample flow 112 with a single line of cells 1467 join an immiscible carrier flow 106 to form droplets 122 at a T-junction 100. The cells 1467 will be automatically encapsulated and protected by the surrounding carrier fluid 104 (in this case, oil). The cells 1467 can be detected optically at 1470 using a laser 1471 and optical sensor 1472, preferably using the method and apparatus disclosed in our U.S. provisional patent application US 60/662,811. When the cell 1467 is detected, a feedback signal 1473 can activate a heater at an outlet branch 1475. Waste 1476 passes along a waste channel 1477. The entire droplet 122 with the cell 1467 inside can then be switched for further processing.

As observed in FIG. 6, the amount of carrying oil may be reduced by a factor of two at each break up process. This effect can be used for a sample concentrator as described below.

In FIG. 15 a sample concentrator is used as a postprocessor. For example, cells sorted and purified in the device described with reference to FIG. 14 can be output to the sample concentrator. In many applications, these cells should be concentrated for further processes such as cell lyses, DNA extraction, DNA amplification and DNA separation. As such, there is a need to have cells 1467 in high concentration in a single phase. The T-junctions 100 for the breakup can be cascaded in N steps. At each junction 100 the amount of encapsulating oil 104 is reduced by a factor of two. For N steps the total oil is reduced to ½^{N} times the original amount. As such the droplets 122 can be combined, merged or joined to form a single large droplet 1578 with a plurality of concentrated cells 1467 inside. The single large droplet 1578 can then be passed through outlet 120 for further processing.

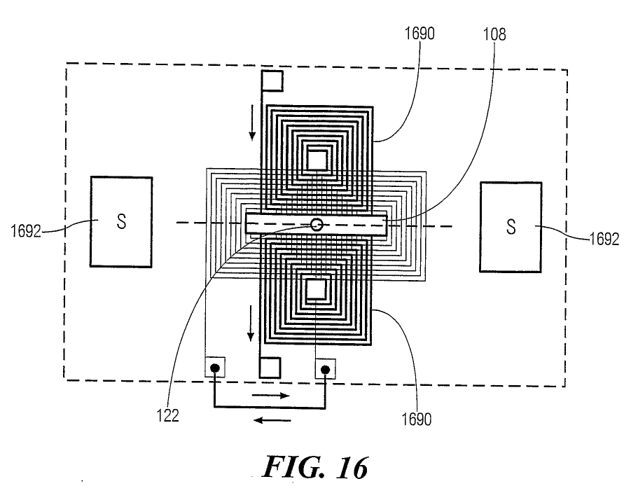

As shown in FIG. 16, active control of the micro-droplets using a magnetic field is possible. With magnetic beads distributed at the droplet interface, the formation and breakup process can be controlled by an external magnetic field formed by an external electromagnet 1690 and, if required, permanent magnets 1692. The magnetic beads can act as an agitator inside a droplet. Agitation as by stirring is therefore possible.

Applications of the exemplary embodiments include a lab-on-a-chip platform for chemical and biochemical analysis, a lab-on-a-chip platform for cell encapsulation and sorting, and a sample concentrator. The exemplary embodiments may used for designing a lab-on-a-chip device. In contrast to well-know droplet-based system with an array of electrodes, a microchannel network is used. This may lead to one of more of:
droplets and carrier liquids being confined in the microchannel to reduce evaporation-related problems;
the use of a central supply of carrier fluid that may be in a reservoir on the platform;
samples being supplied externally or from integrated reservoirs; the continuous delivery of a carrier fluid requiring a relatively simple pumping system; and
the ability to combine with optical detection or impedance detection of the droplet to form a closed-loop control system.

Whilst there has been described in the foregoing description preferred embodiments of the present invention, it will be understood by those skilled in the technology concerned that many variations in details of design, construction and/or operation may be made without departing from the present invention.

1. A microfluidic network for active control of characteristics of at least one micro-droplet, the microfluidic network comprising:
at least one junction of at least one first channel and at least one second channel; and
an electrically controlled actuator at or adjacent the junction to induce a change in the characteristics of the at least one micro-droplet.

2. A microfluidic network as claimed in claim 1, wherein the control of the characteristics of the at least one droplet is selected from the group consisting of: droplet formation, droplet break-up, combining of droplets, joining of droplets, and merging of droplets.

3. A microfluidic network as claimed in claim 1, wherein the electrically controlled actuator is at least one selected from the group consisting of: an actuator for hydrodynamic disturbance, a piezoelectric actuator, at least one microheater, an external electromagnet, and at least one microwetting cell.

4. A microfluidic network as claimed in claim 3, wherein the at least one microwetting cell comprises a first electrode in the at least one first channel, and at least one second electrode at or adjacent the at least one junction.

5. A microfluidic network as claimed in claim 4, wherein the at least one second electrode is insulated with a hydrophobic material.

6. A microfluidic network as claimed in claim 4, wherein the first electrode is able to have direct contact with a sample fluid in the at least one first channel.

7. A microfluidic network as claimed in claim 4, wherein the at least one second channel comprises at least one side branch, the at least one second electrode being in the at least one side branch.

8. A microfluidic network as claimed in claim 7, wherein there are two side branches, there being a first array of second electrodes in a first side branch, and a second array of second electrodes in a second side branch.

9. A microfluidic network as claimed in claim 8, wherein the first array of second electrodes and the second array of second electrodes are separately controllable.

10. A microfluidic network as claimed in claim 3, wherein the piezoelectric actuator is operatively connected to the at least one second channel and effects hydrodynamic disturbance along the at least one second channel to the at least one junction.

11. A microfluidic network as claimed in claim 3, wherein the at least one second channel comprises at least one side branch, the at least one microheater being in the at least one side branch.

12. A microfluidic network as claimed in claim 11, wherein there are two side branches, there being a first array of microheaters in a first side branch, and a second array of microheaters in a second side branch.

13. A microfluidic network as claimed in claim 12, wherein the first array of microheaters and the second array of microheaters are separately controllable.

14. A microfluidic network as claimed in claim 3, wherein the external electromagnetic is used for generating a magnetic field for controlling the characteristics of the at least one micro-droplet.

15. A microfluidic network as claimed in claim 14, wherein magnetic beads are distributable at an interface of the at least one micro-droplet, the external electromagnet controlling the characteristics of the at least one micro-droplet by the external magnetic field.

16. A microfluidic network as claimed in claim 15, wherein the magnetic beads act as an agitator inside the at least one micro droplet.

17. A microfluidic network as claimed in claim 15, wherein agitation by stirring is able to be performed.

18. A microfluidic network as claimed in claim 1, wherein the at least one junction is at least one selected from the group consisting of: a T-junction, a cross junction, a bisected V-junction, and a Y-shaped junction.

19. A lab-on chip device comprising:
a carrier fluid reservoir operatively connected to the second channel of the microfluidic network of claim 1 as claimed in;
an electric signal input to, and an output from, the microfluidic network for sensing characteristics of the microfluidic network controlling the microfluidic network respectively;
an optical signal input to, and an output from, the microfluidic network for sensing characteristics of, and receiving output from, the microfluidic network respectively;
a waste reservoir operatively connected to an output of the microfluidic network for receiving outlet waste carrier fluid; and
at least one reservoir for at least one reagent and at least one sample fluids and being o operatively connected to the at least one first channel.

20. A lab-on-chip device as claimed in claim 19 further comprising at least one selected from the group consisting of: a preprocessor with hydrodynamic focusing, a detection unit, and a cell switching unit.

21. A method for active control of characteristics of at least one micro-droplet using a microfluidic network comprising at least one junction of at least one first channel and at least one second channel, the method comprising:
using an electrically controlled actuator at or adjacent the junction to induce a change in the characteristics of the at least one micro-droplet.

22. A method as claimed in claim 21, wherein the control of the characteristics of the at least one droplet is selected from the group consisting of: droplet formation, droplet break-up, combining of droplets, joining of droplets, and merging of droplets.

23. A method as claimed in claim 21, wherein the electrically controlled actuator is at least one selected from the group consisting of: an actuator for hydrodynamic disturbance, a piezoelectric actuator, at least one microheater, an external electromagnet, and at least one microwetting cell.

24. A method as claimed in claim 23, wherein the at least one microwetting cell comprises a first electrode in the at least one first channel, and at least one second electrode at or adjacent the at least one junction.

25. A method as claimed in claim 24, wherein the at least one second electrode is insulated with a hydrophobic material.

26. A method as claimed in claim 24, wherein the first electrode has direct contact with a sample fluid in the at least one first channel.

27. A method as claimed in claim 24, wherein the at least one second channel comprises at least one side branch, the at least one second electrode being in the at least one side branch.

28. A method as claimed in claim 26, wherein there are two side branches, there being a first array of second electrodes in a first side branch, and a second array of second electrodes in a second side branch.

29. A method as claimed in claim 28, wherein the first array of second electrodes and the second array of second electrodes are separately controlled.

30. A method as claimed in claim 23, wherein the piezoelectric actuator is operatively connected to the at least one second channel and effects hydrodynamic disturbance along the at least one second channel to the at least one junction.

31. A method as claimed in claim 23, wherein the at least one second channel comprises at least one side branch, the at least one microheater being in the at least one side branch.

32. A method as claimed in claim 31, wherein there are two side branches, there being a first array of microheaters in a first side branch, and a second array of microheaters in a second side branch.

33. A method as claimed in claim 32, wherein the first array of microheaters and the second array of microheaters are separately controlled.

34. A method as claimed in claim 23, wherein the external electromagnet forms an external magnetic field to control the characteristics of the at least one micro-droplet.

35. A method as claimed in claim 34, wherein magnetic beads are distributed at an interface of the at least one micro-droplet, the external electromagnet controlling the characteristics of the at least one micro-droplet by the external magnetic field.

36. A method as claimed in claim 35, wherein the magnetic beads act as an agitator inside the at least one micro-a droplet.

37. A method as claimed in claim 35, wherein agitation by stirring is performed.

38. A method as claimed in claim 21, wherein the at least one junction is at least one selected from the group consisting of: a T-junction, a cross junction, a bisected V-junction, and a Y-shaped junction.

39. A sample concentrator for concentrating a plurality of micro-droplets each containing a cell into a single, large droplet containing a plurality of ceils, the sample concentrator comprising:
a plurality of microfluidic networks as claimed in claim 1, at each junction of the at least one junction of each of the plurality of micro fluidic networks there being an outlet for removal of carrier fluid.
